(19) United States
(12) Patent Application Publication
(10) Pub. No.: US 2026/0103805 A1
(43) Pub. Date: Apr. 16, 2026

(54) SHIELD FOR ENHANCED PRECURSOR PURGING

(71) Applicant: Applied Materials, Inc., Santa Clara, CA (US)

(72) Inventors: Suraj Suresh Babu, Bangalore (IN); Dhritiman Subha Kashyap, Bangalore (IN); Ashutosh Agarwal, San Jose, CA (US); Shreya Dhar, Sunnyvale, CA (US)

(73) Assignee: Applied Materials, Inc., Santa Clara, CA (US)

(21) Appl. No.: 18/911,713

(22) Filed: Oct. 10, 2024

(51) Int. Cl. C23C 16/458; C23C 16/44; C23C 16/455

(52) U.S. Cl. CPC C23C 16/4585; C23C 16/4408; C23C 16/4586; C23C 16/45544

(57) ABSTRACT

Purge shields for processing chambers, substrate supports assemblies and processing chamber using the purge shields are described. The purge shield comprises a top plate, a bottom plate, and an center shaft connecting the top plate to the bottom plate. The top flange has an annular channel formed in the top surface with a plurality of openings extending through the thickness of the top plate. The center shaft has a plurality of wall openings extending through the thickness of the center shaft wall.

### TECHNICAL FIELD

Embodiments of the disclosure are directed to purge shields for semiconductor manufacturing processing chambers. In particular, embodiments of the disclosure are directed to purge shields for semiconductor manufacturing that prevent back diffusion of precursors.

### BACKGROUND

During an atomic layer deposition (ALD) process, reactant gases are introduced separately into a process chamber containing a substrate. Generally, a region of a substrate is contacted with a first reactant which is adsorbed onto the substrate surface. The substrate is then contacted with a second reactant which reacts with the first reactant to form a deposited material. A purge gas may be introduced between the deliveries of each reactant gas to ensure that the only reactions that occur are on the substrate surface.

In current semiconductor manufacturing process chambers, heater purge goes through a ferroseal, which is a vacuum seal that allows dynamic sealing using a ferrofluid. A ferrofluid is a liquid that is attracted to the poles of a magnet. The high flow rates used in the vacuum seal increase the risk of ferroseal damage which can result in exposing the process gas to the ferrofluid and causing contamination of the ferrofluid and/or the process chamber.

Accordingly, there is a need in the art for apparatus and methods to improve purge gas flow.

### SUMMARY

One or more embodiments of the disclosure are directed to purge shields comprising a top plate, a bottom plate and a center shaft. The top plate has a top surface and a bottom surface. The top surface of the top plate having an annular channel formed in an outer peripheral portion of the top surface. A plurality of openings extend through the top plate from the bottom of the annular channel to the bottom surface of the top plate. The bottom plate has a top surface and a bottom surface. The center shaft connects the top surface of the bottom plate with the bottom surface of the top plate. An opening extends a length of the purge shield from the top surface of the top plate to the bottom surface of the bottom plate and defines a central axis of the purge shield. The opening has an inner diameter. A plurality of wall openings extend through a wall thickness of the center shaft.

Additional embodiments of the disclosure are directed to support assemblies comprising a rotatable center base, at least two support arms, a heater and a purge shield. The at least two support arms are connected to the rotatable center base and have an inner end and an outer end. The heater is positioned at the outer end of the support arms. Each of the heaters has a support surface and a bottom surface. Each heater is positioned on a heater standoff so that the bottom surfaces of the heaters are spaced a distance from the support arms. The purge shield is positioned at the outer end of the support arms. The purge shield is positioned around the heater standoffs. The purge shield comprises a top plate, a bottom plate and a center shaft. The top plate has a top surface and a bottom surface. The top surface is positioned a distance from the bottom surface of the heater. The top surface of the top plate has an annular channel formed in an outer peripheral portion of the top surface. A plurality of openings extend through the top plate from the bottom of the annular channel to the bottom surface of the top plate. The bottom plate has a top surface and a bottom surface. The bottom surface is in contact with the support arm. The center shaft connects the top surface of the bottom plate with the bottom surface of the top plate. An opening extends a length of the purge shield from the top surface of the top plate to the bottom surface of the bottom plate. The opening defines a central axis of the purge shield. The opening is configured to surround the heater standoff. A plurality of wall openings extends through a wall thickness of the center shaft.

### BRIEF DESCRIPTION OF THE DRAWINGS

So that the manner in which the above recited features of the disclosure are attained and can be understood in detail, a more particular description of the disclosure, briefly summarized above, may be had by reference to the embodiments thereof which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 shows a cross-sectional isometric view of a processing chamber in accordance with one or more embodiments of the disclosure;

FIG. 2 shows a cross-sectional view of a processing chamber in accordance with one or more embodiments of the disclosure;

FIG. 3 illustrates a support assembly in accordance with one or more embodiments of the disclosure;

FIG. 4 illustrates a support assembly in accordance with one or more embodiments of the disclosure;

FIG. 5 shows an expanded view of a portion of a support assembly in which the channel is shown;

FIG. 6 illustrates a portion of a processing chamber showing a process station with gas injector and pedestal including a purge shield according to one or more embodiments of the disclosure;

FIG. 7 shows a schematic representation of a pedestal with purge shield according to one or more embodiments if the disclosure.

FIG. 8 shows an isometric view of a purge shield according to one or more embodiments of the disclosure;

FIG. 9 illustrates a cross-sectional view of the purge shield of FIG. 8 taken along line 9-9′;

FIG. 10 shows an expanded view of region X of FIG. 9;

FIG. 11 shows an expanded view of region X of FIG. 9; and

FIG. 12 shows an expanded view of region XII of FIG. 9.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” or “wafer” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

“Atomic layer deposition” or “cyclical deposition” as used herein refers to a process comprising the sequential exposure of two or more reactive compounds to deposit a layer of material on a substrate surface. “Atomic layer deposition” or “cyclical deposition” as used herein refers to a process comprising the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas. The gas curtain can be any suitable gas separation arrangement known to the skilled artisan. For example, in some embodiments of a spatial ALD process chamber, a gas curtain is formed by a combination of purge gas ports and vacuum ports to maintain separation between the reactive gases to prevent gas-phase reactions. In some embodiments of a spatial ALD process chamber, separate process stations are configured to form a mini-process environment within each station.

As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction, cycloaddition). The substrate, or portion of the substrate, is exposed sequentially to the two or more reactive compounds which are introduced into a reaction zone of a processing chamber.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of “about.” Spatially relative terms, such as “beneath,” “below,” “lower,” “above,” “upper” and the like, may be used herein for ease of description to describe one element or feature's relationship to another element(s) or feature(s) as illustrated in the Figures. It will be understood that the spatially relative terms are intended to encompass different orientations of a device in use or operation in addition to the orientation depicted in the figures. For example, if the device in the Figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

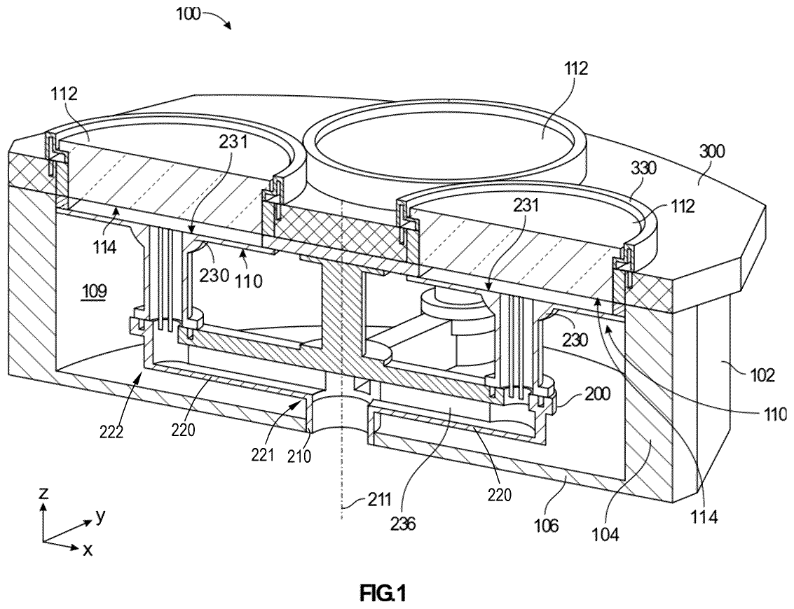

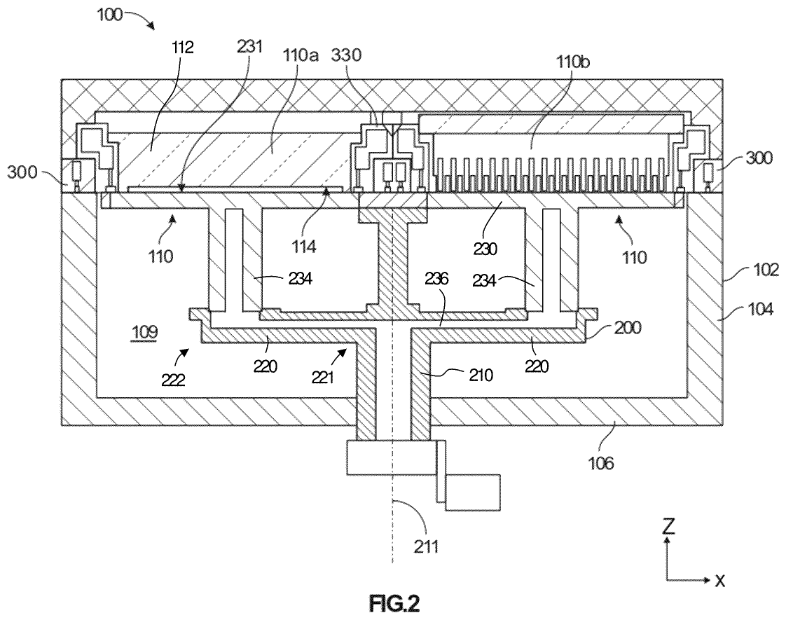

Embodiments of the disclosure are directed to substrate supports (also referred to as pedestals) for use with single substrate or multi-substrate (also referred to as batch) process chambers. FIGS. 1 and 2 illustrate a batch processing chamber 100 in accordance with one or more embodiment of the disclosure. FIG. 1 shows the processing chamber 100 illustrated as a cross-sectional isometric view in accordance with one or more embodiment of the disclosure. FIG. 2 shows a processing chamber 100 in cross-section according to one or more embodiment of the disclosure.

The processing chamber 100 has a housing 102 with walls 104 and a bottom 106. The housing 102 along with the top plate 300 define a interior volume 109, also referred to as a processing volume.

The processing chamber 100 illustrated includes a plurality of processing stations 110. The processing stations 110 are located in the interior volume 109 of the housing 102 and are positioned in a circular arrangement around the rotational axis 211 of the support assembly 200. Each processing station 110 comprises a gas injector 112 (also referred to as a gas distribution plate) having a front surface 114. The processing stations 110 are defined as a region in which processing can occur. For example, in some embodiments, a processing station 110 is defined as a region bounded by the support surface 231 of the support assembly 200, as described below, and the front surface 114 of the gas injectors 112. In the illustrated embodiment, heaters 230 act as the substrate support surfaces and form part of the support assembly 200.

The processing stations 110 can be configured to perform any suitable process and provide any suitable process conditions. The type of gas injector 112 used will depend on, for example, the type of process being performed and the type of showerhead or gas injector. For example, a processing station 110 configured to operate as an atomic layer deposition apparatus may have a showerhead or vortex type gas injector. Whereas, a processing station 110 configured to operate as a plasma station may have one or more electrode and/or grounded plate configuration to generate a plasma while allowing a plasma gas to flow toward the substrate. The embodiment illustrated in FIG. 2 has a different type of processing station 110 on the left side (processing station 110a) of the drawing than on the right side (processing station 110b) of the drawing. Suitable processing stations 110 include, but are not limited to, thermal processing stations, microwave plasma, three-electrode CCP, ICP, parallel plate CCP, UV exposure, laser processing, pumping chambers, annealing stations and metrology stations.

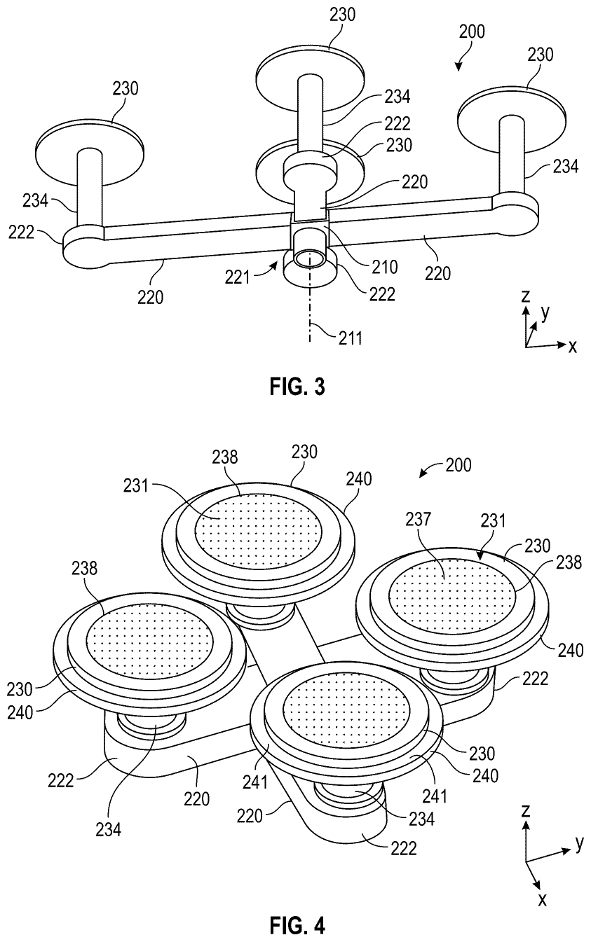

FIGS. 3 through 5 illustrate support assemblies 200 in accordance with one or more embodiments of the disclosure. With reference to FIGS. 1-5, support assembly 200 includes a rotatable center base 210. The rotatable center base 210 can have a symmetrical or asymmetrical shape and defines a rotational axis 211. The rotational axis 211, as can be seen in FIGS. 1 through 3, extends in a first direction. The first direction may be referred to as the vertical direction or along the z-axis. The use of the term “vertical” is not limited to a direction parallel to the pull of gravity, and the use of the term “horizontal”is not limited to a direction normal to the pull of gravity.

The support assembly 200 includes at least two support arms 220 connected to and extending from the center base 210. The support arms 220 have an inner end 221 and an outer end 222. The inner end 221 is in contact with the center base 210 so that when the center base 210 rotates around the rotational axis 211, the support arms 220 rotate as well. In some embodiments, the support arms 220 extend orthogonal to the rotational axis 211 so that the outer ends 222 are further from the rotational axis 211 than the inner ends 221 of the same support arm 220.

The support arms 220 can be connected to the center base 210 by any suitable manner known to the skilled artisan. For example, in some embodiments, the inner end 221 is connected to the center base 210 by use of fasteners (e.g., bolts). In some embodiments, the inner end 221 is integrally formed with the center base 210.

The number of support arms 220 in the support assembly 200 can vary. In some embodiments, there are at least two support arms 220, at least three support arms 220, at least four support arms 220, or at least five support arms 220. In some embodiments, there are three support arms 220. In some embodiments, there are four support arms 220. In some embodiments, there are five support arms 220. In some embodiments, there are six support arms 220.

The support arms 220 of some embodiments are arranged symmetrically around the center base 210. For example, in a support assembly 200 with four support arms 220, each of the support arms 220 are positioned at 90° intervals around the center base 210 so that an axis formed by the support arms 220 are perpendicular to an axis formed by an adjacent (not across the rotation axis 211) support arm 220. Stated differently, in embodiments with four support arms 220, the support arms are arrange to provide four-fold symmetry around the rotation axis 211. In a support assembly 200 with three support arms 220, the support arms 220 are positioned at 120° intervals around the center base 210 so that an axis formed by the support arms 220 are at a 120° angle to the other support arms 220. In some embodiments, the support assembly 200 has n-number of support arms 220 and the n-number of support arms 220 are arranged to provide n-fold symmetry around the rotation axis 211.

A heater 230 is positioned at the outer end 222 of the support arms 220. In some embodiments, each support arm 220 has a heater 230. The center of the heaters 230 are located at a distance from the rotational axis 211 so that upon rotation of the center base 210 around rotation axis 211, the heaters 230 move in a circular path around rotation axis 211.

The heaters 230 have a support surface 231 configured to support a substrate or wafer. In some embodiments, the heater 230 support surfaces 231 are substantially coplanar. As used in this manner, “substantially coplanar” means that the planes formed by the individual support surfaces 231 are within ±5°, ±4°, ±3°, ±2° or ±1° of the planes formed by the other support surfaces 231.

In some embodiments, the heaters 230 are positioned directly on the outer end 222 of the support arms 220. In some embodiments, as illustrated in the drawings, the heaters 230 are elevated above the outer end 222 of the support arms 220 by a heater standoff 234. The heater standoffs 234 can be any size and length to increase the height of the heaters 230. The term “pedestal” is used to refer to a heater standoff 234 with a support surface 231 connected to the top end of the standoff. The support surface 231 can be part of the heater 230 or part of a different component without a heating element.

In some embodiments, a channel 236 is formed in one or more of the center base 210, the support arms 220 and/or the heater standoffs 234. The channel 236 can be used to route electrical connections for the heaters 230, electrical connections for an electrostatic chuck or to provide a gas flow.

The heaters 230 can be any suitable type of heater known to the skilled artisan. In some embodiments, the heater 230 is a resistive heater with one or more heating elements within a heater body.

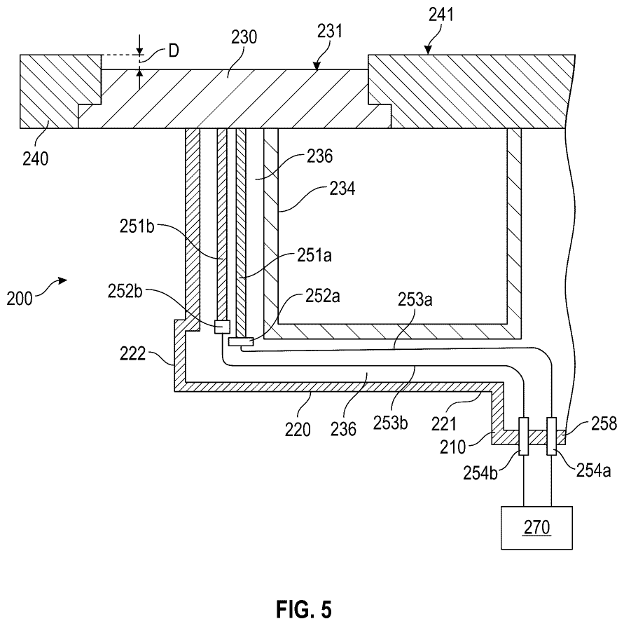

The heaters 230 of some embodiments include additional components. For example, the heaters may comprise an electrostatic chuck. The electrostatic chuck can include various wires and electrodes so that a wafer positioned on the heater support surface 231 can be held in place while the heater is moved. This allows a wafer to be chucked onto a heater at the beginning of a process and remain in that same position on that same heater while moving to different process regions. In some embodiments, the wires and electrodes are routed through the channels 236 in the support arms 220. FIG. 5 shows an expanded view of a portion of a support assembly 200 in which the channel 236 is shown. The channel 236 extends along the support arm 220 and the heater standoff 234. A first electrode 251a and second electrode 251b are in electrical communication with heater 230, or with a component inside heater 230 (e.g., a resistive wire or an electrostatic chuck). In the illustrated embodiment, a first wire 253a connects to first electrode 251a at first connector 252a; and a second wire 253b connects to second electrode 251b at second connector 252b. In some embodiments, there are more than two wires. For example, in an example embodiment with a heating element and an electrostatic chuck, at least two wires are in contact with the heating element and at least two wires are in contact with the electrostatic chuck.

In some embodiments, a temperature measuring device (e.g., pyrometer, thermistor, thermocouple) is positioned within the channel 236 to measure one or more of the heater 230 temperature or the temperature of a substrate on the heater 230. In some embodiments, the control and/or measurement wires for the temperature measurement device are routed through the channel 236. In some embodiments, one or more temperature measurement devices are positioned within the processing chamber 100 to measure the temperature of the heaters 230 and/or a wafer on the heaters 230. Suitable temperature measurement devices are known to the skilled artisan and include, but are not limited to, optical pyrometers and contact thermocouples.

The wires can be routed through the support arms 220 and the support assembly 200 to connect with a power source (not shown). In some embodiments, the connection to the power source allows continuous rotation of the support assembly 200 without tangling or breaking the wires 253a, 253b. In some embodiments, as shown in FIG. 5, the first wire 253a and second wire 253b extend along the channel 236 of the support arm 220 to the center base 210. In the center base 210 the first wire 253a connects with center first connector 254a and the second wire 253b connects with center second connector 254b. The center connectors 254a, 254b can be part of a connection plate 258 so that power or electronic signals can pass through center connectors 254a, 254b. In the illustrated embodiment, the support assembly 200 can rotate continuously without twisting or breaking wires because the wires terminate in the center base 210. In some embodiments, the support assembly 200 is configured to allow rotation up to about 360° without twisting or breaking wires. A second connection is on the opposite side of the connection plate 258 (outside of the processing chamber).

In some embodiments, the wires are connected directly or indirectly to a power supply 270 or electrical component outside of the processing chamber through the channel 236. In embodiments of this sort, the wires have sufficient slack to allow the support assembly 200 to be rotated a limited amount without twisting or breaking the wires. In some embodiments, the support assembly 200 is rotated less than or equal to about 1080°, 990°, 720°, 630°, 360° or 270° before the direction of rotation is reversed. This allows the heaters 230 to be rotated through each of the stations 110 without breaking the wires.

Referring to FIG. 4, the heater 230 and support surface 231 can include one or more gas outlets (or openings 237) to provide a flow of backside gas. The backside gas may assist in the removal of the wafer from the support surface 231 or allow for other processes to occur, as described below. As shown in FIG. 4, the support surface 231 includes a plurality of openings 237 and a gas channel 238. The openings 237 and/or gas channel 238 can be in fluid communication with one or more of a vacuum source or a gas source (e.g., a purge gas or reactive gas). In embodiments of this sort, a gas line can be included to allow fluid communication of a gas source with the openings 237 and/or gas channel 238.

Embodiments of the disclosure provide purge shields in which a portion of the bottom purge is bypassed as a heater purge through holes on shield shaft. This purge flow reduces the risk of leakage and eliminates the need for a separate heater purge. Additionally, a separate heater purge requires a separate mass flow controller (MFC) which increases the equipment costs.

One or more embodiments of the disclosure provide purge shield designs that split a single purge flow into a bottom purge and separate purge (e.g., a heater purge). Some embodiments optimize the purging process to prevent precursor diffusion into the heater-shield cavity.

Embodiments of the disclosure provide improved shield designs to prevent back diffusion of precursors and reactive gases around the pedestal and into the thermal shield space. Some embodiments include a lip seal between the top plate and the shield to minimize precursor back diffusion.

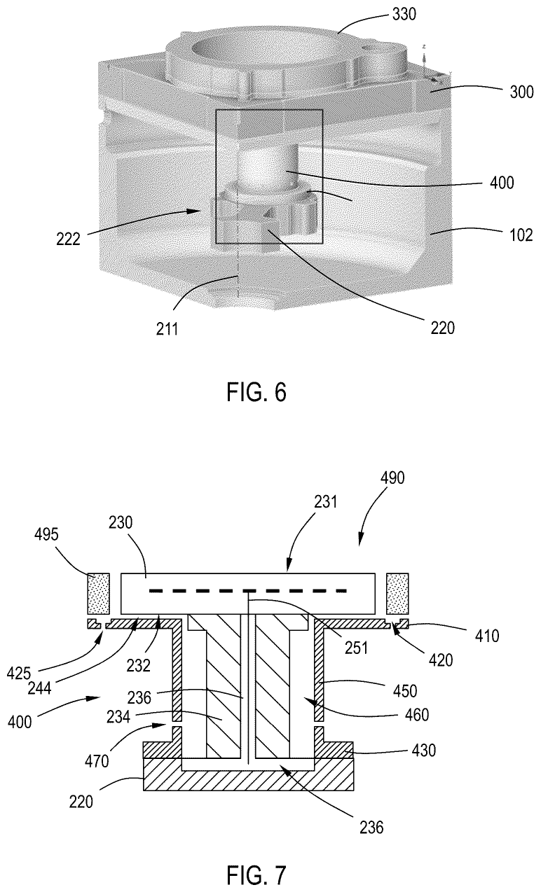

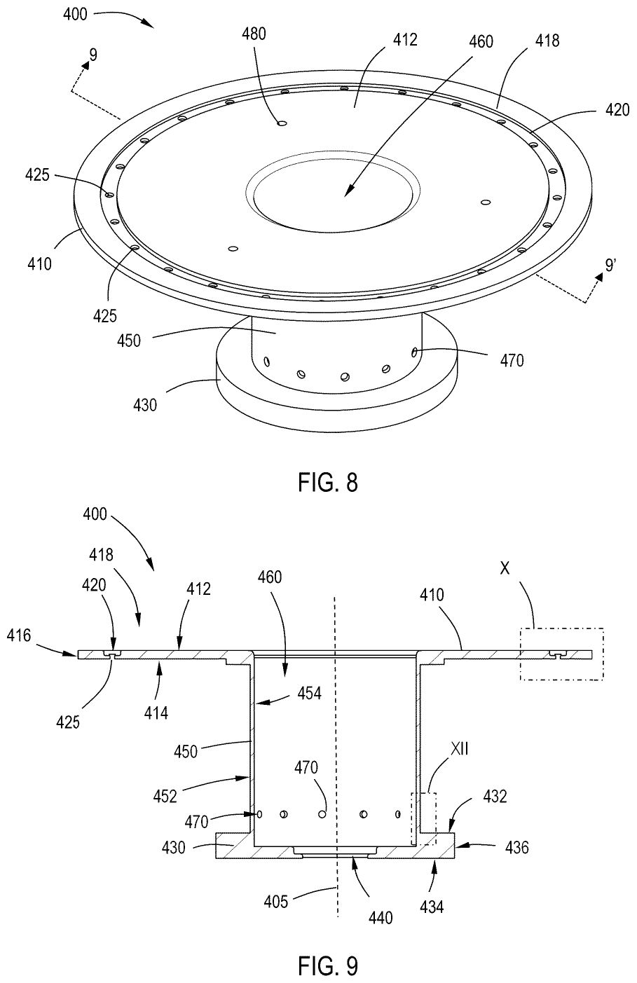

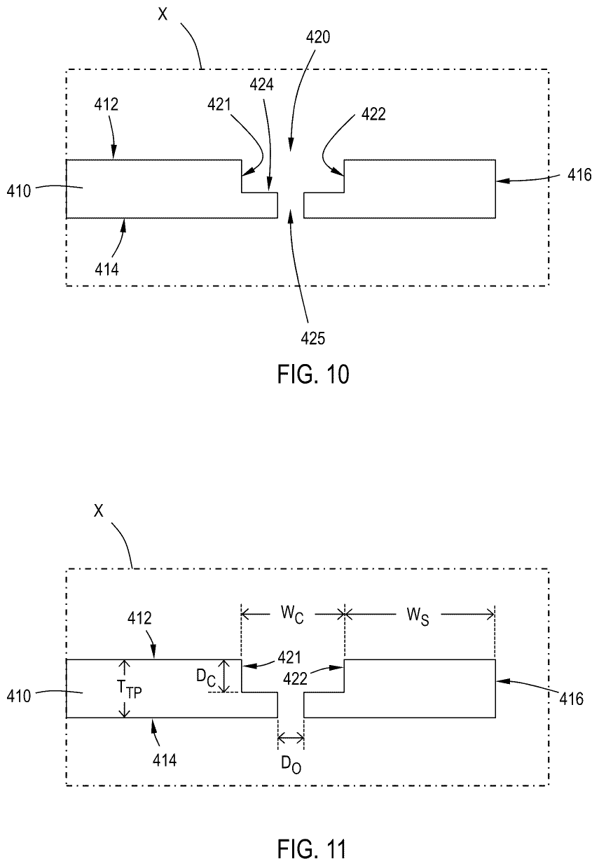

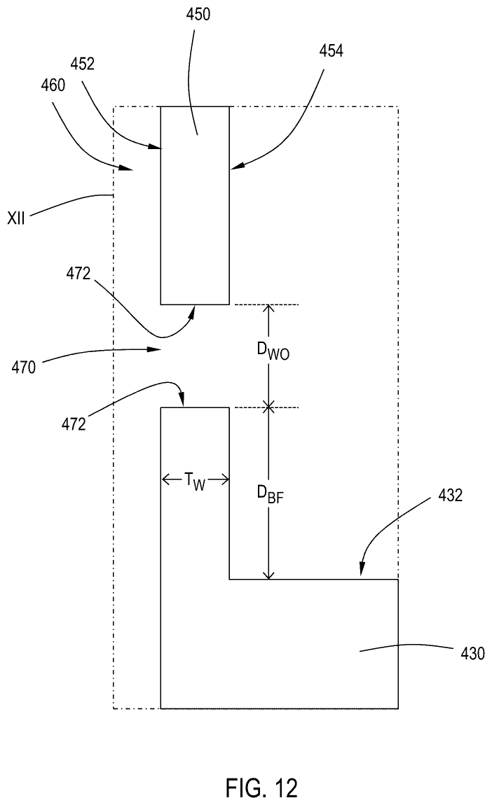

FIG. 6 illustrates a portion of a processing chamber showing a process station with gas injector and pedestal including a purge shield according to one or more embodiments of the disclosure. FIG. 7 shows a schematic representation of a pedestal with purge shield according to one or more embodiments if the disclosure. FIG. 8 shows an isometric view of a purge shield according to one or more embodiments of the disclosure. FIG. 9 illustrates a cross-sectional view of the purge shield of FIG. 8 taken along line 9-9′. FIG. 10 shows an expanded view of region X of FIG. 9. FIG. 11 shows an expanded view of region X of FIG. 9. FIG. 12 shows an expanded view of region XII of FIG. 9.

With reference to FIGS. 6 through 12, one or more embodiments of the disclosure are directed to purge shields 400. In particular, the purge shields 400 are configured for use in a semiconductor manufacturing processing chamber. However, the skilled artisan will recognize that the purge shields 400 can be used in any suitable apparatus in which a split flow of gas around a separate component (e.g., a pedestal or heater assembly) is useful.

The purge shield 400 of some embodiments comprises a top plate 410, a bottom plate 430 and a center shaft 450 connecting the top plate 410 to the bottom plate 430. The top plate 410 has a top surface 412 and a bottom surface 414 that define a thickness T_{TP} of the top plate 410.

The top plate 410 has an outer peripheral face 416 that defines the outer diameter of the top plate 410. The outer diameter of the top plate 410 can vary depending on, for example, the size of the heater 230 or the wafer to be processed. For example, in one or more embodiments, the wafer being processed has a 300 mm diameter and the outer diameter of the heater 230 is larger than the diameter of the wafer, the top plate 410 has an outer diameter in the range of 350 mm to 500 mm. The skilled artisan will recognize that the outer diameter is not limited to the recited range and that other outer diameters are within the scope of the disclosure. The top plate of some embodiments of the purge shield has an outer diameter greater than the diameter of the substrate support surface. In some embodiments, when a 300 mm wafer is being processed, the top plate has an outer diameter in the range of 350 mm to 500 mm, or in the range of 375 mm to 475 mm, or in the range of 400 mm to 450 mm, or about 425 mm.

The top plate 410 includes an annular channel 420 formed in an outer peripheral portion 418 of the top surface 412. The annular channel of some embodiments acts as a plenum on the top plate 410. The annular channel 420 has an inner face 421 and an outer face 422 that define the width W_{C} of the annular channel 420, as shown in FIGS. 10 and 11. The annular channel 420 has a bottom surface 424 that defines the depth D_{C} of the annular channel 420 measured from the top surface 412 of the top plate 410, as shown in FIGS. 10 and 11.

The dimensions and location of the annular channel 420 can vary. In some embodiments, the annular channel 420 has a width W_{C}, defined from the inner face 421 to the outer face 422, in the range of 20 mm to 40 mm, or in the range of 25 mm to 35 mm. In some embodiments, the annular channel 420 has a depth DC in the range of 3.5 mm to 5 mm, or in the range of 3.75 mm to 4.75 mm, or in the range of 4 mm to 4.5 mm. In some embodiments, the annular channel has a width of about 30 mm, and a depth of about 4.25 mm. However, both the width and depth are merely exemplary of a particular embodiment, and other widths, depths, inner diameters and outer diameters are within the scope of the disclosure.

In some embodiments, as shown in FIG. 7, the top plate 410 has holes 425 that provide an alternate path for separation purge gas and bottom purge gas to get inside the heater-shield cavity 244. The annular channel 420 includes a plurality of openings 425 that extend from the bottom surface 424 of the annular channel 420 to the bottom surface 414 of the top plate 410. Each of the plurality of openings 425 in the top plate 410 has a diameter D_{O} (shown in FIG. 11). The diameter D_{O} can be the same for all of the plurality of openings 425, or the diameter D_{O} of the openings can vary around the top plate 410. In some embodiments, each of the plurality of openings 425 in the top plate 410 independently has a diameter D_{O} in the range of 1 mm to 5 mm. In some embodiments, the plurality of openings 425 in the bottom of the annular channel 420 have the same diameter D_{O} in the range of 1 mm to 5 mm, or in the range of 2 mm to 4 mm. In some embodiments, the plurality of openings 425 in the annular channel 420 have the same diameter D_{O} of 3 mm.

The plurality of openings 425 can have any suitable number of openings. In some embodiments, there are in the range of 8 to 96, or in the range of 12 to 72, or in the range of 16 to 60, or in the range of 20 to 36, or in the range of 22 to 30 openings in the plurality of openings 425 in the top plate 410. In some embodiments, there are 24 openings in the plurality of openings 425.

The locations of the plurality of openings 425 in the top plate 410 can be uniformly spaced, or non-uniformly spaced around the annular channel 420. In some embodiments, the plurality of openings 425 in the top plate 410 are spaced symmetrically around the central axis 405 of the purge shield 400. For example, in an embodiment with 24 openings in the plurality of openings 425, each of the openings is spaced around the annular channel 420 at 15° increments, relative to the central axis 405 of the purge shield 400. In a particular embodiment, there are 24 holes with diameter of 3 mm each spaced evenly around the annular channel 420.

The bottom plate 430 of the purge shield 400 of some embodiments acts as a flange to allow the purge shield 400 to be connected to a separate component. For example, one or more fasteners can be positioned within openings (not shown) in the bottom plate 430 to secure the purge shield 400 to the support arms 220. Any suitable fastener known to the skilled artisan can be used including, but not limited to, screws, bolts, welding or brazing.

The bottom plate 430 has a top surface 432 and a bottom surface 434 that define the thickness of the bottom plate 430. The outer peripheral face 436 of the bottom plate 430 defines the outer diameter of the bottom plate 430. In some embodiments, the bottom plate 430 includes a bottom opening 440 with an inner diameter. The bottom opening 440 illustrated in FIG. 9 has a stepped portion, with each step having a different inner diameter. The bottom opening 440 of some embodiments allows for a flow of gas to pass through the bottom plate 430.

The center shaft 450 of the purge shield 400 connects the top surface 432 of the bottom plate 430 to the bottom surface 414 of the top plate 410. In some embodiments, the top plate 410, bottom plate 430 and center shaft 450 are integrally formed as a single component.

The center shaft 450 is a hollow cylinder to allow a flow of gas passing through the bottom opening 440 to flow through the opening 460 which flows through the center shaft 450. The center shaft 450 has an inner surface 452 and an outer surface 454 that define the thickness T_{W} of the center shaft 450. The opening 460 extends the length of the purge shield 400 measured from the top surface 412 of the top plate 410 to the bottom surface 434 of the bottom plate 430. The inner diameter of the opening 460 can be uniform or vary. For example, in the embodiment illustrated in FIG. 9, the opening 460 is mostly uniform along the length of the purge shield 400, with a smaller stepped bottom opening 440 that extends through the bottom plate 430, and a larger inner diameter at the small fillet at the top surface 412 of the top plate 410.

In some embodiments, there are holes in the shield shaft to allow a sufficient flow of purge gas to flow into the shield cavity. In some embodiments, the holes in the shield shaft eliminate or minimize the need for separate heater purge setup. The center shaft 450 of some embodiments has a plurality of wall openings 470 that extend through the wall thickness T_{W} of the center shaft 450.

The wall openings 470 can be any suitable shape. In some embodiments, the wall openings 470 are circular with an inner diameter face 472 and an inner diameter D_{WO}. The inner diameter D_{WO} of the plurality of wall openings 470 can vary around the periphery of the center shaft 450 or can be uniform. In some embodiments, the holes in the center shaft 450 have a diameter in the range of 1 mm to 7 mm, or in the range of 2 mm to 6 mm, or in the range of 3 mm to 5 mm, or 4 mm. In some embodiments, each of the wall openings 470 in the center shaft 450 independently has a diameter in the range of 3 mm to 5 mm. In some embodiments, the plurality of wall openings 470 have an inner diameter D_{WO} that is greater than the inner diameter D_{O} of the plurality of openings 425 in the annular channel 420.

The plurality of wall openings 470 are spaced around the periphery of the center shaft 450. The spacing of the wall openings 470 can be uniform or staggered. In some embodiments, the plurality of wall openings 470 are evenly spaced around the center shaft 450, or the central axis 405 of the purge shield 400.

The number of wall openings in the plurality of wall openings 470 can vary depending on, for example, the diameter of the wall openings. In some embodiments, there are in the range of 4 to 24, or in the range of 6 to 22, or in the range of 8 to 20, or in the range of 10 to 16, or 12 openings in the plurality of wall openings 470. In some embodiments, there are less openings in the plurality of wall openings 470 in the center shaft 450 than there are openings in the plurality of openings 425 in the annular channel 420 in the top plate 410. In a particular embodiment, the purge shield 400 has a center shaft 450 with 12 wall openings evenly spaced around the center shaft 450 (around the central axis 405) and each of the wall openings in the plurality of wall openings 470 have a 4 mm inner diameter.

Referring to FIG. 8, in some embodiments, the top plate 410 has a plurality of lift pin openings 480 that extend through the thickness of the top plate 410. The number of lift pin openings 480 can be any suitable number and the diameter of the lift pin openings can be any suitable diameter depending on, for example, the number and diameter of lift pins being used. In the illustrated embodiment, there are three lift pin openings 480 in the top plate 410.

Referring to FIG. 7, some embodiments of the disclosure are directed to a substrate support assembly 490. The support assembly 490 comprises a rotatable center base 210 with at least two support arms 220 extending from the rotatable center base 210. Each of the support arms 220 has an inner end 221 connected to the rotatable center base 210, and an outer end 222 a distance from the rotatable center base 210. A heater 230 is positioned at the outer end 222 of the support arms 220. Each of the heaters 230 has a support surface 231 and a bottom surface 232. The heaters 230 are positioned on a heater standoff 234. The purge shield 400 is positioned at the outer end 222 of the support arms 220 around the heater standoff 234. The bottom surface 232 of the heaters 230 are spaced a distance from the top surface 412 of the top plate 410 to create a heater-shield cavity 244 in which a gas can flow. In some embodiments, the top surface 412 of the top plate 410 is polished to a smooth surface. The polished surface of the top plate 412 can be used to reflect heat from the heater 230 back towards the heater 230.

Some embodiments of the disclosure are directed to processing chambers comprising the support assembly 490 with the purge shield 400. In some embodiments, as shown in FIG. 7, a lip seal 495 is positioned around the outer periphery of the heater 230 and spaced a distance from the top surface 412 of the top plate 410. The lip seal 495 of some embodiments seals the gap between the top plate 410 and the heater 230. In some embodiments, the lip seal 495 is positioned over at least a portion of the annular channel 420 of the purge shield 400.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A purge shield comprising:
a top plate having a top surface and a bottom surface, the top surface of the top plate having an annular channel formed in an outer peripheral portion of the top surface, and a plurality of openings extending through the top plate from a bottom of the annular channel to the bottom surface of the top plate;
a bottom plate having a top surface and a bottom surface;
a center shaft connecting the top surface of the bottom plate with the bottom surface of the top plate;
an opening extends a length of the purge shield from the top surface of the top plate to the bottom surface of the bottom plate and defining a central axis of the purge shield, the opening having an inner diameter; and
a plurality of wall openings extending through a wall thickness of the center shaft.

2. The purge shield of claim 1, wherein each of the plurality of openings in the top plate independently has a diameter in the range of 1 mm to 5 mm.

3. The purge shield of claim 1, wherein there are in the range of 20 to 36 openings in the top plate.

4. The purge shield of claim 1, wherein the plurality of openings in the top plate are spaced symmetrically around the central axis of the purge shield.

5. The purge shield of claim 1, wherein there are 24 openings in the top plate, and each of the plurality of openings has a 3 mm diameter.

6. The purge shield of claim 1, wherein the annular channel has a width from an inner diameter face to an outer diameter face in the range of 20 mm to 40 mm.

7. The purge shield of claim 1, wherein the annular channel has a depth from the top surface of the top plate to the bottom of the annular channel in the range of 3.5 mm to 5 mm.

8. The purge shield of claim 1, wherein there are in the range of 8 to 20 wall openings in the center shaft.

9. The purge shield of claim 1, wherein each of the wall openings in the center shaft independently has a diameter in the range of 3 mm to 5 mm.

10. The purge shield of claim 1, wherein the wall openings are evenly spaced around the center shaft.

11. The purge shield of claim 1, wherein there are 12 wall openings evenly spaced around the center shaft, each of the wall openings having a 4 mm diameter.

12. The purge shield of claim 1, wherein the top plate has an outer diameter in the range of 350 mm to 500 mm.

13. A support assembly comprising:
a rotatable center base;
at least two support arms connected to the rotatable center base and having an inner end and an outer end;
a heater positioned at the outer end of the support arms, each of the heaters having a support surface and a bottom surface, each heater positioned on a heater standoff so that bottom surfaces of the heaters are spaced a distance from the support arms; and
a purge shield positioned at the outer end of the support arms, the purge shield positioned around heater standoff, the purge shields comprising:
a top plate having a top surface and a bottom surface, the top surface of the top plate positioned a distance from the bottom surface of the heater, the top surface of the top plate having an annular channel formed in an outer peripheral portion of the top surface, and a plurality of openings extending through the top plate from a bottom of the annular channel to the bottom surface of the top plate;
a bottom plate having a top surface and a bottom surface, the bottom surface in contact with the support arm;
a center shaft connecting the top surface of the bottom plate with the bottom surface of the top plate;
an opening extends a length of the purge shield from the top surface of the top plate to the bottom surface of the bottom plate and defining a central axis of the purge shield, the opening configured to surround the heater standoff; and
a plurality of wall openings extending through a wall thickness of the center shaft.

14. The support assembly of claim 13, wherein there are four support arms connected to the rotatable center base, each of the support arms having a purge shield at an outer end thereof.

15. The support assembly of claim 13, wherein each of the plurality of openings in the top plate independently has a diameter in the range of 1 mm to 5 mm.

16. The support assembly of claim 13, wherein there are in the range of 20 to 36 openings in the top plate.

17. The support assembly of claim 13, wherein the plurality of openings in the top plate are spaced symmetrically around the central axis of the purge shield.

18. The support assembly of claim 13, wherein there are in the range of 8 to 20 wall openings in the center shaft.

19. The support assembly of claim 13, wherein each of the wall openings in the center shaft independently has a diameter in the range of 3 mm to 5 mm.

20. A processing chamber comprising the support assembly of claim 13.
